(19) United States
(12) Patent Application Publication
(10) Pub. No.: US 2026/0182055 A1
(43) Pub. Date: Jun. 25, 2026

(54) IMAGE SENSOR

(71) Applicant: SAMSUNG ELECTRONICS CO., LTD., Suwon-si (KR)

(72) Inventors: Yuri JEONG, Suwon-si (KR); Je-Hyung RYU, Suwon-si (KR); Hajin LIM, Suwon-si (KR); Keewon KIM, Suwon-si (KR); Jaesung HUR, Suwon-si (KR)

(73) Assignee: SAMSUNG ELECTRONICS CO., LTD., Suwon-si (KR)

(21) Appl. No.: 19/289,657

(22) Filed: Aug. 4, 2025

(30) Foreign Application Priority Data
Dec. 24, 2024 (KR) 10-2024-0196169

(51) Int. Cl. H10F 39/00; H10F 39/18

(52) U.S. Cl. CPC H10F 39/805; H10F 39/182; H10F 39/8053; H10F 39/809

(57) ABSTRACT

Provided is an image sensor, including a substrate including a first surface and a second surface opposite to each other in a first direction, a wiring layer on the first surface of the substrate, an anti-reflection layer on the second surface of the substrate, the anti-reflection layer including a TiO₂ layer that includes a first region having a first refractive index and a second region having a second refractive index greater than the first refractive index, and a plurality of color filters on the anti-reflection layer, wherein at least a portion of the second region and at least a portion of the first region overlap with each other in a second direction that intersects with the first direction.

### CROSS-REFERENCE TO RELATED APPLICATION

This application claims priority to Korean Patent Application No. 10-2024-0196169, filed in the Korean Intellectual Property Office on Dec. 24, 2024, the disclosure of which is incorporated herein in its entirety by reference.

### BACKGROUND

### 1. Field

Embodiments of the present disclosure relate to an image sensor.

### 2. Description of Related Art

An image sensor is a semiconductor device that converts an optical image into an electrical signal. The image sensor can be classified into a charge coupled device (CCD) type and a complementary metal oxide semiconductor (CMOS) type. The CMOS type image sensor may be referred to as a CMOS image sensor (CIS). The CIS may include a plurality of pixels arranged in two dimensions. Each of the pixels may include a photoelectric conversion device, such as photodiode (PD). The photoelectric conversion device may be operated to convert incoming light into electric signals. The incoming light may enter the photoelectric conversion device through a color filter. In order to increase sensitivity of the image sensor, an anti-reflection layer, adjusted for high transmittance by modifying a refractive index, may be disposed between the color filter and the photoelectric conversion device.

The information described above is intended to improve understanding of the background of the present disclosure, and may include information that does not constitute the related art.

### SUMMARY

One or more embodiments provide an image sensor.

An object to be achieved by the present disclosure is not limited thereto, and other objects not explicitly described herein may be clearly understood by those skilled in the art from the description of the present disclosure.

According to an aspect of one or more embodiments, there is provided an image sensor, including a substrate including a first surface and a second surface opposite to each other in a first direction, a wiring layer on the first surface of the substrate, an anti-reflection layer on the second surface of the substrate, the anti-reflection layer including a TiO₂ layer that includes a first region having a first refractive index and a second region having a second refractive index greater than the first refractive index, and a plurality of color filters on the anti-reflection layer, wherein at least a portion of the second region and at least a portion of the first region overlap with each other in a second direction that intersects with the first direction.

According to another aspect of one or more embodiments, there is provided an image sensor, including a first semiconductor chip including a first substrate including a photoelectric conversion element (PD) region that comprises a plurality of photoelectric conversion elements in a two-dimensional array and a peripheral region outside the PD region, and a first wiring layer on a first surface of the first substrate, a second semiconductor chip on the first semiconductor chip, the second semiconductor chip including a second substrate, a logic device being on the second substrate and a second wiring layer being on a first surface of the second substrate, an anti-reflection layer on a second surface of the first substrate opposite to the first surface of the first substrate, the anti-reflection layer including a first region having a first refractive index and a second region having a second refractive index greater than the first refractive index, and a color filter layer on the anti-reflection layer and including a plurality of color filters in a two-dimensional array within the PD region, wherein the first region is on a first portion of the color filter layer, and wherein the second region is on a second portion of the color filter layer other than the first portion of the color filter layer.

According to still another aspect of one or more embodiments, there is provided an image sensor, including a first semiconductor chip including a first substrate that includes a first surface and a second surface opposite to each other in a first direction, and a first wiring layer on the first surface of the first substrate, the first substrate including a photoelectric conversion element (PD) region that comprises a plurality of photoelectric conversion elements in a two-dimensional array and a peripheral region outside the PD region, a second semiconductor chip on the first semiconductor chip, the second semiconductor chip including a second substrate, a logic device being on the second substrate and a second wiring layer being on a first surface of the second substrate, an anti-reflection layer on the second surface of the first substrate, the anti-reflection layer including a TiO₂ layer that includes a first region having a first refractive index and a second region having a second refractive index greater than the first refractive index, and a color filter layer on the anti-reflection layer, the color filter layer including a plurality of color filters in a two-dimensional array within the PD region, wherein at least a portion of the second region and at least a portion of the first region overlap with each other in a second direction that intersects with the first direction, wherein the first region includes at least one of amorphous TiO₂ or anatase phase TiO₂, wherein the second region includes rutile phase TiO₂ and at least one of the amorphous TiO₂, or the anatase phase TiO₂, wherein each color filter of the plurality of color filters includes one of a red filter, a blue filter, or a green filter, wherein the first region is on the blue filter, and wherein the second region is on the red filter or the green filter.

According to still another aspect of one or more embodiments, there is provided a method of forming an image sensor, the method including forming a first substrate including a first surface and a second surface opposite to each other in a first direction, forming a wiring layer the first surface of the first substrate, forming a second substrate on the wiring layer, forming anti-reflection layer on the second surface of the first substrate, the anti-reflection layer including a TiO2 layer that includes a first region having a first refractive index and a second region having a second refractive index greater than the first refractive index, and forming a plurality of color filters on the anti-reflection layer, wherein at least a portion of the second region and at least a portion of the first region overlap with each other in a second direction that intersects with the first direction.

The method may further include forming the first region to correspond to some color filters of the plurality of color filters and forming the second region to correspond to remaining color filters of the plurality of color filters.

The method may further include forming a plurality of microlenses on the plurality of color filters.

### BRIEF DESCRIPTION OF DRAWINGS

The above and other objects, features and advantages of the present disclosure will become more apparent to those of ordinary skill in the art by describing in detail exemplary aspects thereof with reference to the accompanying drawings, in which:

FIG. 1 is a block diagram provided to explain an image sensor according to one or more embodiments;

FIG. 2 is an example diagram provided to explain an image sensor according to one or more embodiments;

FIG. 3 is a diagram provided to explain an equivalent circuit diagram of a unit pixel according to one or more embodiments;

FIG. 4 is a plan view provided to explain an image sensor according to one or more embodiments;

FIG. 5 is a cross-sectional view of the I-I′ portion of FIG. 4;

FIG. 6 is a graph illustrating the light transmittance according to the wavelength of each crystal phase of titanium oxide (TiO₂);

FIG. 7 is a diagram provided to explain an image sensor according to one or more embodiments;

FIG. 8 is a diagram provided to explain a color filter layer according to one or more embodiments;

FIG. 9 is a diagram provided to explain an arrangement of a first region and a second region below a color filter layer according to one or more embodiments;

FIG. 10 is a diagram provided to explain an image sensor according to one or more embodiments;

FIG. 11 is a diagram provided to explain an arrangement of a first region and a second region below a color filter layer according to one or more embodiments;

FIG. 12 is an example diagram provided to explain an image sensor according to one or more embodiments;

FIG. 13 is a diagram provided to explain an arrangement of a first region and a second region below a color filter layer according to one or more embodiments;

FIG. 14 is an example diagram provided to explain an image sensor according to one or more embodiments; and

FIGS. 15, 16, 17, 18, 19, 20, 21, 22, 23, 24, 25, 26, 27, and 28 are cross-sectional views sequentially illustrating a method of manufacturing the image sensor.

### DETAILED DESCRIPTION

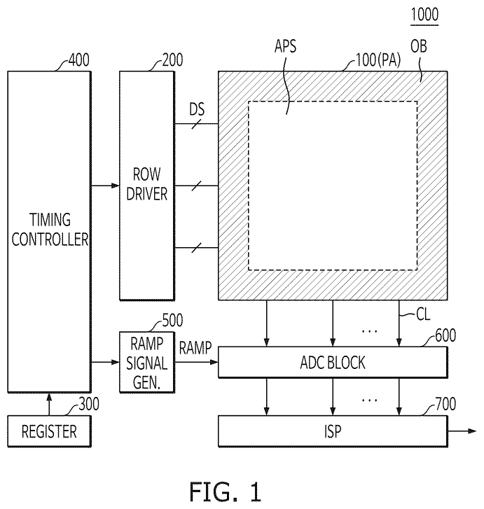

Hereinafter, various embodiments will be described with reference to FIGS. 1 to 28. Throughout the description, the same reference numerals may refer to the same components.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

FIG. 1 is a block diagram provided to explain an image sensor according to one or more embodiments.

An image sensor 1000 may convert an optical signal of an object entering through the optical lens into image data. The image sensor 1000 may be, for example, a charge coupled device (CCD) image sensor or a complementary metal oxide semiconductor (CMOS) image sensor.

The image sensor 1000 may be mounted on an electronic device with an image or light sensing function. For example, the image sensor 1000 may be mounted on electronic devices such as cameras, smartphones, wearable devices, Internet of Things (IoT) devices, home appliances, tablet PCs, navigations, drones, and advanced drivers assistance systems (ADASs). In another example, the image sensor 1000 may be mounted on an electronic device provided as a component in a vehicle, furniture, manufacturing facilities, doors, various measurement devices, etc.

Referring to FIG. 1, the image sensor 1000 may include a pixel region PA 100, a row driver 200, a mode setting register 300, a timing controller 400, a ramp signal generator 500, an analog-to-digital converter (ADC) block 600, and an image signal processor 700.

The pixel region 100 may include a pixel array region APS and an optical blocking region OB. As illustrated in FIG. 1, the pixel array region APS may be disposed in a central region of the pixel region 100, and the optical blocking region OB may be disposed in an outer region of the pixel region 100 surrounding and adjacent to the pixel array region APS. For reference, the pixel array region APS may be referred to as an active pixel sensor region. In addition, the optical blocking region OB may be referred to as an optical black pixel region. A plurality of unit pixels in a two-dimensional arrangement may be disposed in each of the pixel array region APS and the optical blocking region OB. The unit pixels may convert optical signals into electrical signals. The unit pixels of the pixel region 100 may output the electrical signals through column lines CL corresponding to the unit pixels in response to a plurality of driving signals DS such as a pixel select signal, a reset signal, or a charge transfer signal received from the row driver 200 on a row basis.

The row driver 200 may select and drive the unit pixels of the pixel region 100 on a row basis. The row driver 200 may decode row control signals (e.g., address signals) received from the timing controller 400, generate a plurality of driving signals DS corresponding to the decoded row lines, and transmit the generated signals to the pixel region 100.

The mode setting register 300 may be a register through which an application processor AP connected to the image sensor 1000 sets an operation mode of the image sensor 1000 via an interface. For example, the application processor may change the operating conditions of the image sensor 1000 on a frame basis through the mode setting register 300.

The timing controller 400 may control the operations of the row driver 200, the ramp signal generator 500, the ADC block 600, and the image signal processor 700 according to mode setting information set in the mode setting register 300.

The ramp signal generator 500 may generate a ramp signal RAMP that increases or decreases with a predetermined slope and provide the ramp signal RAMP to the ADC block 600.

The ADC block 600 may convert an analog electrical signal output from the column line CL of the pixel region 100 into a digital image signal with a Correlated Double Sampling (CDS) method. The ADC block 600 may double sample a noise level and a signal level of the unit pixel transmitted to the column line CL, and convert a difference level corresponding to the difference between the noise level and the signal level into a digital image signal.

The image signal processor 700 may process the received image signal and output a final image signal. The signal processing of the image signal processor 700 may include noise reduction processing, gain adjustment, waveform shaping processing, interpolation processing, white balance processing, gamma processing, edge enhancement processing, binning, etc.

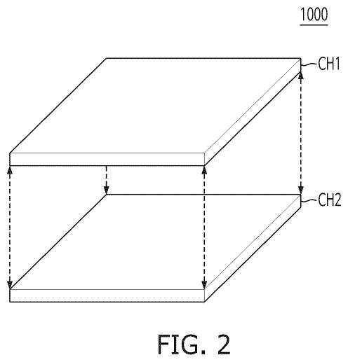

FIG. 2 is an example diagram provided to explain an image sensor according to one or more embodiments. While describing one or more embodiments by referring to FIG. 2 and also to FIG. 1, the aspects already described above in relation to FIG. 1 will be briefly described or will not be described.

Referring to FIG. 2, the image sensor 1000 according to one or more embodiments may include two semiconductor chips CH1 and CH2. The pixel region 100 of the image sensor 1000 of FIG. 1 may be disposed on a first semiconductor chip CH1. Circuit blocks 200, 300, 400, 500, 600, and 700 excluding the pixel region 100 may be disposed in the second semiconductor chip CH2. The first semiconductor chip CH1 and the second semiconductor chip CH2 may be stacked on each other. The first semiconductor chip CH1 and the second semiconductor chip CH2 may transmit and receive signals to and from each other through respective wiring layers and a through silicon via (TSV) or inter-chip connection terminal formed through the first semiconductor chip CH1.

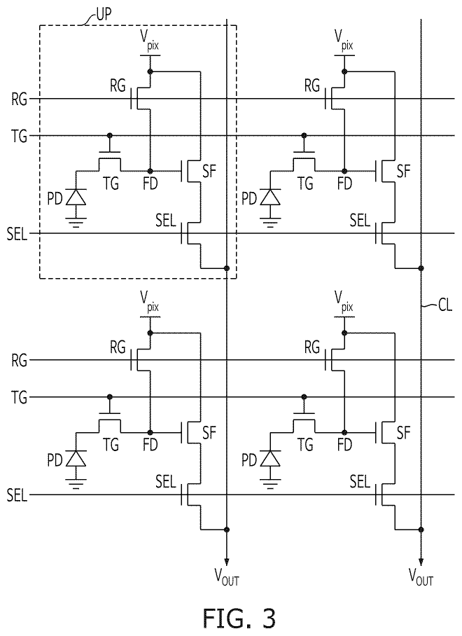

The image sensor 1000 according to one or more embodiments may include three stacked semiconductor chips. When the image sensor 1000 includes three stacked semiconductor chips, some of the components of the unit pixels may be disposed in the first semiconductor chip CH1 at the top of the first semiconductor chip CH1. For example, a photodiode (e.g., see PD in FIG. 3), a transfer transistor (e.g., see TG in FIG. 3), and a floating diffusion region (e.g., see FD in FIG. 3) of the unit pixels may be disposed in the first semiconductor chip. In the second semiconductor chip CH2 located below the first semiconductor chip CH1, pixel transistors other than the transfer transistor TG, such as a reset transistor (e.g., see RG in FIG. 3), a source follower transistor (e.g., see SF in FIG. 3), and a select transistor (e.g., see SEL in FIG. 3), may be disposed. The transfer transistor TG and the floating diffusion region FD of the first semiconductor chip CH1 may be connected to the corresponding pixel transistors RG, SF, SEL of the second semiconductor chip through the TSV or the inter-chip connection terminal. The circuit blocks 200 through 700 may be disposed in a third semiconductor chip located below the second semiconductor chip CH2. The third semiconductor chip may be connected to the second semiconductor chip through the TSV or the inter-chip connection terminal.

FIG. 3 is a diagram provided to explain an equivalent circuit diagram of a unit pixel according to one or more embodiments. While describing one or more embodiments by referring to FIG. 3 and also to FIG. 1, the aspects already described above in relation to FIG. 1 or 2 will be briefly described or will not be described.

Referring to FIG. 3, the pixel region 100 may include a plurality of unit pixels UP, and the unit pixels UP may be arranged in a two-dimensional array structure. The unit pixel UP may include a photodiode PD and pixel transistors. The pixel transistors may include a transfer transistor TG, a reset transistor RG, a source follower transistor SF, and a selection transistor SEL. In addition, the unit pixel UP may include a floating diffusion region FD connected to the transfer transistor TG, the reset transistor RG, and the source follower transistor SF.

The photodiode PD may generate and accumulate electrical charges in proportion to an amount of incident light received from outside during the exposure time. In one or more embodiments, a photo transistor, a photo gate, a pinned photo diode (PPD), or any combination thereof may be disposed instead of the photodiode PD. A device that converts light into electrical charges is called a photoelectric conversion device.

The transfer transistor TG may transmit charges accumulated in the photodiode PD during the exposure time to the floating diffusion region FD in response to a transmission control signal. The transmission control signal may be applied through the transfer transistor TG. The electrical charges transferred from the photodiode PD through the transfer transistor TG may be stored in the floating diffusion region FD. The voltage of a gate of the source follower transistor SF may be determined according to the amount of electrical charges stored in the floating diffusion region FD.

The reset transistor RG may reset the charge stored in the floating diffusion region FD. A source of the reset transistor RG may be connected to the floating diffusion region FD, and a drain may be connected to a power supply voltage Vₚᵢₓ. When the reset transistor RG is turned on by a reset control signal, the power supply voltage Vₚᵢₓ of a drain of the reset transistor RG may be applied to the floating diffusion region FD. The reset control signal may be applied through a reset transistor RG. When the reset transistor RG is turned on and the power supply voltage Vₚᵢₓ of the drain of the reset transistor RG is applied to the floating diffusion region FD, the charges stored in the floating diffusion region FD may be released and the voltage of the floating diffusion region FD may be reset to the power supply voltage Vₚᵢₓ.

The source follower transistor SF may include a gate connected to the floating diffusion region FD, a drain connected to the power supply voltage Vₚᵢₓ, and a source connected to the selection transistor SEL. The source follower transistor SF may serve as a source follower buffer amplifier which generates an output voltage at the source in response to the voltage of the gate.

The selection transistor SEL may transmit the output voltage of the source of the source follower transistor SF to the column line CL in response to a column select signal. The column select signal may be applied through a selection transistor SEL. The source follower transistor SF and the selection transistor SEL may sense a voltage change of the floating diffusion region FD and output an output voltage V_{OUT} to the column line CL.

In FIG. 3, it is illustrated that for each unit pixel UP, one floating diffusion region FD and the corresponding pixel transistors RG, SF, SEL are disposed on a 1:1 basis with one photodiode PD, but embodiments are not limited thereto. In another example, for a unit pixel of a relatively high-resolution image sensor, a shared pixel structure may be formed, in which a plurality of photodiodes PD share one floating diffusion region FD and the corresponding pixel transistors RG, SF, SEL.

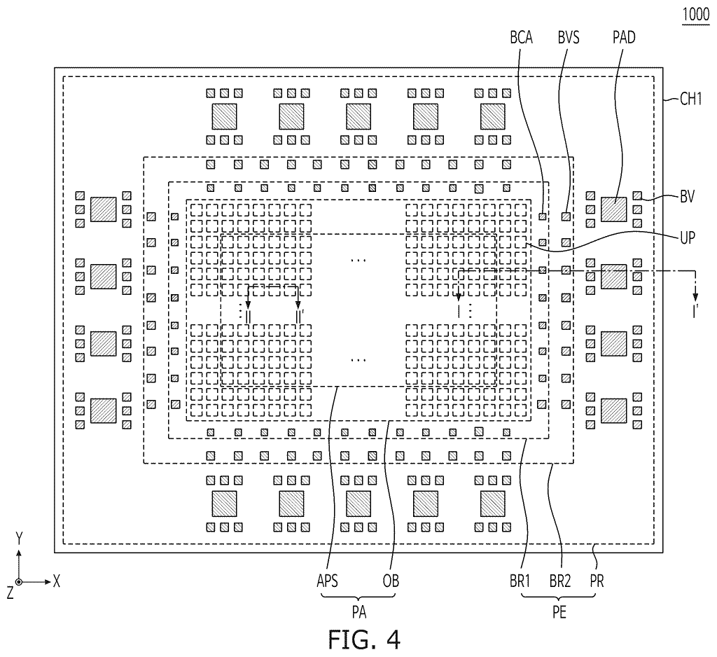

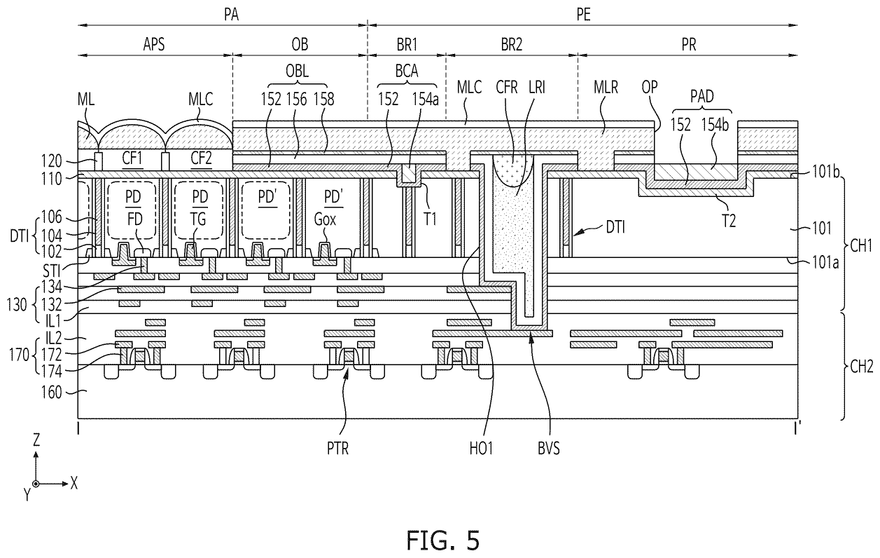

FIG. 4 is a plan view provided to explain an image sensor according to one or more embodiments. FIG. 5 is a cross-sectional view of the I-I′ portion of FIG. 4. While describing one or more embodiments by referring to FIGS. 4 and 5 and also to FIG. 1, the aspects already described above in relation to FIG. 1 FIG. 3 will be briefly described or will not be described.

Referring to FIGS. 4 and 5, the image sensor 1000 may include the first semiconductor chip CH1 and the second semiconductor chip CH2. In one or more embodiments, the first semiconductor chip CH1 may be stacked on the second semiconductor chip CH2.

The first semiconductor chip CH1 may include a first substrate 101. The first substrate 101 may include silicon (Si). The first substrate 101 may be, for example, a single crystal silicon substrate, a silicon epitaxial layer substrate, or a silicon-on-insulator (SOI) substrate. However, the material of the first substrate 101 is not limited to silicon (Si). For example, the first substrate 101 may include another single-element semiconductor such as germanium (Ge), or a compound semiconductor such as silicon carbide (SiC), gallium arsenide (GaAs), indium arsenide (InAs), or indium phosphide (InP). The first substrate 101 may be doped with, for example, impurities of a first conductivity type. The first conductivity type may be P-type. However, the first conductivity type is not limited to the P-type. The first substrate 101 may include a first surface 101a and a second surface 101b opposite to each other in a Z direction perpendicular to the first surface 101a of the substrate 100. The first surface 101a may be referred to as a front side of the first substrate 101 and the second surface 101b may be referred to as a back side of the first substrate 101, but embodiments are not limited thereto.

Referring to FIG. 4, the image sensor 1000 may include a pixel region PA and a peripheral region PE. As described in FIG. 1, the pixel region PA may include a pixel array region APS and an optical blocking region OB. A plurality of unit pixels UP may be disposed in the pixel array region APS and the optical blocking region OB. As illustrated in FIG. 4, the optical blocking region OB may be disposed to surround the pixel array region APS. Although FIG. 4 illustrates the pixel array region APS with a relatively narrow area in the center, and the optical blocking region OB and the peripheral region PE with relatively large areas, this is provided for convenience of description. In the image sensor 1000 according to one or more embodiments, the pixel array region APS may occupy a larger area in the center of the first semiconductor chip CH1, and the optical blocking region OB and the peripheral region PE may be disposed with narrower areas outside the pixel array region APS.

The peripheral region PE may be disposed adjacent to and to surround the pixel region PA, for example, the optical blocking region OB. The peripheral region PE may include, for example, a contact region BR1, a backside via stack region BR2, and a pad region PR. The contact region BR1 may be disposed adjacent to the optical blocking region OB. In the contact region BR1, backside contacts BCA may be disposed at predetermined intervals along a line surrounding the optical blocking region OB.

The backside via stack region BR2 may be disposed between the contact region BR1 and the pad region PR. Backside via stacks BVS may be disposed in the backside via stack region BR2. In FIG. 4, it is illustrated that the backside via stacks BVS are disposed in one row around the contact region BR1, but embodiments are not limited thereto. For example, the backside via stacks BVS may be disposed in a two-dimensional array structure in the backside via stack region BR2. In addition, it is illustrated that the backside via stacks BVS are disposed adjacent to four sides of the contact region BR1, but embodiments are not limited thereto. For example, the backside via stacks BVS may not be disposed on at least one side surface of the contact region BR1. In one or more embodiments, a shield region may be defined (formed) between the contact region BR1 and the pad region PR, and the backside via stack region BR2 may be disposed in a portion of the shield region.

The pad region PR may be disposed in an outermost region of the peripheral region PE. The backside vias BV and the pads PAD may be disposed in the pad region PR. Although the pad region PR with a relatively wide width, in an X direction and/or a Y direction parallel to the first surface 101a of the substrate 100, is illustrated in FIG. 4, this may be an exaggerated illustration to provide a clearer representation of an example arrangement structure of the pads PAD and the surrounding backside vias BV.

Referring to FIG. 5, a PD isolation pattern DTI may be formed in the first substrate 101 of the pixel array region APS and the optical blocking region OB such that the unit pixels UP may be separated from each other. As illustrated in FIG. 5, the PD isolation part DTI may also be formed in the contact region BR1 and the backside via stack region BR2 of the peripheral region PE. The PD isolation part DTI may be formed in a planar mesh shape when viewed from the Z direction. The PD isolation part DTI may be formed in a structure that penetrates the first substrate 101 in the Z direction. With the PD isolation part DTI formed in the structure penetrating the first substrate 101, crosstalk caused by the obliquely incoming light may be prevented.

The PD isolation part DTI may be formed in a front DTI (FDTI) structure extending from the first surface 101a to the second surface 101b of the first substrate 101. The PD isolation part DTI may be formed in a back DTI (BDTI) structure extending from the second surface 101b to the first surface 101a of the first substrate 101.

The PD isolation part DTI may include an insulating pattern 102, a side insulating layer 104, and a conductive pattern 106. The insulating pattern 102 may be interposed between the conductive pattern 106 and a first interlayer insulating film IL1. The side insulating layer 104 may be disposed adjacent to and to surround the exterior of the conductive pattern 106. The conductive pattern 106 may be insulated from the first substrate 101 by the side insulating layer 104.

The insulating pattern 102 and the side insulating layer 104 may include an insulating material having a refractive index different from that of the first substrate 101. The insulating pattern 102 and the side insulating layer 104 may include, for example, silicon oxide, silicon nitride, silicon oxynitride, etc. The conductive pattern 106 may be spaced apart from the first substrate 101 by the side insulating layer 104. The conductive pattern 106 may include impurity-doped polysilicon, silicon germanium, etc. The impurities doped into the polysilicon or silicon germanium may include, for example, boron, phosphorus, arsenic, etc. The conductive pattern 106 may include metal, metal silicide, metal-containing conductive material, etc.

The photodiode PD may be doped with impurities of a second conductivity type opposite to the first conductivity type. For example, the second conductivity type may be N-type. However, the second conductivity type is not limited to the N-type. The region doped with the N-type impurity may form a PN junction with the adjacent first substrate 101 doped with the P-type impurity to form a photodiode PD.

The first substrate 101 may be a semiconductor substrate in which a photoelectric conversion (PD) region that comprises a plurality of photoelectric conversion elements in a two-dimensional array, and a peripheral region (PE) located outside the PD region are defined, and may include the first surface 101a and the second surface 101b facing each other in the Z direction. Here, the photoelectric conversion elements may correspond to photodiodes (PD) illustrated in FIG. 3. The photoelectric conversion region (PD) may correspond to a pixel region (PA) in which the photoelectric conversion elements are arranged within the first substrate 101.

A shallow trench isolation pattern STI may be disposed adjacent to the first surface 101a of the first substrate 101. The PD isolation part DTI may be penetrated by the shallow trench isolation pattern STI. In one or more embodiments, a structure may be formed, in which the PD isolation part DTI is in contact with the shallow trench isolation pattern STI. An active region may be defined in the unit pixel UP by the shallow trench isolation pattern STI. The transistors of the unit pixel UP, for example, the transfer transistor TG, the reset transistor RG, the source follower transistor SF, or the selection transistor SEL of FIG. 3 may be disposed in the active region.

A transfer transistor TG of the transfer transistor TG of the unit pixel UP may be disposed on the first surface 101a of the first substrate 101. The transfer transistor TG may be formed in a vertical gate structure in which a portion of the transfer transistor TG extends into the first substrate 101. According to one or more embodiments, the transfer transistor TG may be formed in a planar gate structure which is disposed only on the first surface 101a of the first substrate 101. A gate insulating film Gox may be interposed between the transfer transistor TG and the first substrate 101. The floating diffusion region FD may be disposed in the first substrate 101 on one side of the transfer transistor TG. The floating diffusion region FD may be doped with, for example, the impurities of second conductivity type.

In one or more embodiments, the image sensor 1000 may be an image sensor of back side illumination (BSI) structure. The BSI structure may refer to a structure in which color filters CF1 and CF2 and micro lenses ML are disposed on the second surface 101b of the first substrate 101, and a first wiring layer 130 is disposed on the first surface 101a of the first substrate 101. In the BSI structure, the light may enter the photodiode PD of the pixel array region APS (PD region) through the second surface 101b of the first substrate 101. Electron-hole pairs may be generated in the photodiode PD by the light incident on the photodiode PD, and electrons may be accumulated. When the transfer transistor TG is turned on, electrons accumulated in the photodiode PD may be transmitted to the floating diffusion region FD. For reference, in addition to the BSI structure, the front side illumination (FSI) structure that may be applicable to the image sensor 1000 may refer to a structure in which the color filters CF1 and CF2, the micro lenses ML, and the first wiring layer 130 are disposed on the first surface 101a of the first substrate 101.

The first semiconductor chip CH1 may include the first wiring layer 130 disposed on the first surface 101a of the first substrate 101. The first wiring layer 130 may include the first interlayer insulating film IL1, a first wiring line 132, and a first via contact 134. The first interlayer insulating film IL1 may include at least one of silicon oxide, silicon nitride, silicon oxynitride, or a porous low-k material. Further, the first interlayer insulating film IL1 may be formed in a multilayer structure. The first wiring line 132 may be disposed in the first interlayer insulating film IL1. The first wiring line 132 may be formed in a multilayer structure corresponding to the multilayer structure of the first interlayer insulating film IL1. The first wiring lines 132 of different layers may be connected to each other by the first via contact 134 formed through at least a portion of the first interlayer insulating film IL1. In addition, the first wiring line 132 may be connected to the floating diffusion region FD and the transfer transistor TG through the first via contact 134.

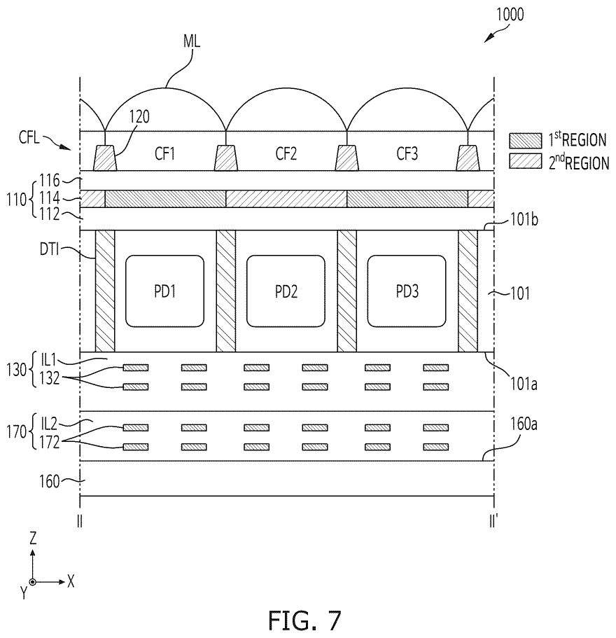

An anti-reflection layer 110 may be disposed on the second surface 101b of the first substrate 101. The anti-reflection layer 110 may be disposed in the pixel region PA and the peripheral region PE. Further, the anti-reflection layer 110 may not be disposed on the backside contact BCA, the backside via stack BVS, or the backside via (BV of FIG. 4). The anti-reflection layer 110 may be formed in a multilayer structure, and may include a TiO₂ layer (e.g., referring to 114 of FIG. 7). In one or more embodiments, the TiO₂ layer may include a first region and a second region having different refractive indices. At least a portion of the first region and at least a portion of the second region may be arranged to overlap with each other in the X direction and/or the Y direction, that is, planarly. The anti-reflection layer 110 may play a role of suppressing the reflection of light incident on the photodiode PD and increasing an amount of light incident on the photodiode PD, according to a thickness of each layer in the Z direction or refractive index of each layer. According to various embodiments, the image sensor 1000 includes the anti-reflection layer 110 in which regions having different refractive indices are optimized and disposed, thereby minimizing the reflection of light in a specific region and increasing the amount of light incident on the photodiode PD. Accordingly, pixel sensitivity of the image sensor 1000 may be improved, and performance or image quality of the image sensor 1000 may be more effectively improved.

A lattice pattern 120 may be disposed on the anti-reflection layer 110 of the pixel array region APS. The lattice pattern 120 may have a planar mesh shape and may be disposed to overlap with at least a portion of the PD isolation part DTI in the Z direction.

The color filters CF1 and CF2 may be disposed in the lattice of the lattice pattern 120 on the anti-reflection layer 110. The color filters CF1 and CF2 may be isolated from each other by the lattice pattern 120. The color filters CF1 and CF2 may be disposed to correspond to each unit pixel UP. Further, the color filters CF1 and CF2 may have various colors according to the unit pixel UP. For example, the color filters CF1 and CF2 may be any one of a red filter, a green filter, or a blue filter. The red filter may pass the wavelength of the red region among the wavelengths of the visible region. The green filter may pass the wavelength of the green region among the wavelengths of the visible region. The blue filter may pass the wavelength of the blue region among the wavelengths of the visible region. However, embodiments are not limited to the above, and the color filters CF1 and CF2 may further include at least one of a yellow filter, a magenta filter, a cyan filter, or a white filter. The yellow filter may pass the wavelength in a range of 500 nm to 600 nm among the wavelengths of the visible region. The magenta filter may pass the wavelength in a range of 400 nm to 480 nm among the wavelengths of the visible region. The cyan filter may pass the wavelength in a range of 450 to 550 nm among the wavelengths of the visible region. The white filter may pass all wavelengths of the visible region.

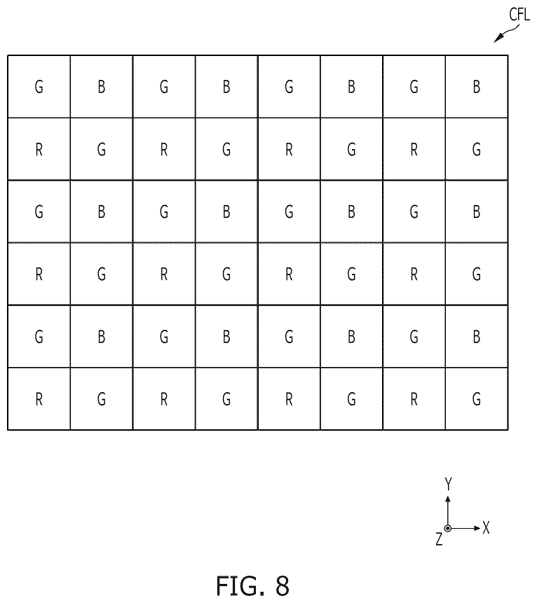

In one or more embodiments, the color filters CF1 and CF2 may be arranged in the form of a Bayer pattern, but embodiments are not limited thereto. The Bayer pattern may refer to a pattern in which, within a unit pattern in the form of a 2×2 array, two green filters are disposed along one diagonal direction, and one blue filter and one red filter are disposed along the other diagonal direction. The arrangement of the color filters CF1 and CF2 will be described below with reference to FIG. 8.

The optical blocking layer OBL may be disposed on the anti-reflection layer 110 of the optical blocking region OB of the first substrate 101. The optical blocking layer OBL may play a role of blocking the light incident on the photodiode PD′ formed on the first substrate 101 of the optical blocking region OB. The photodiode PD′ formed in the optical blocking region OB may have the same structure as a structure of the photodiode PD formed in the pixel array region APS (PD region), but may not perform the same operation (i.e., operation of generating an electrical signal according to the amount of incoming light) as the photodiode PD. For example, since the light incident on the photodiode PD′ is blocked, the photodiode PD′ may generate a dark level reference signal. The image signal processor 700 of FIG. 1 may compensate for the dark level of the output value of the pixels in the pixel array region APS based on the dark level reference signal generated by the photodiode PD′.

The optical blocking layer OBL may include a first conductive layer 152, a first insulating layer 156, and a second insulating layer 158. Additionally, the optical blocking layer OBL may further include an additional conductive layer disposed between the first insulating layer 156 and the second insulating layer 158. Some of light incident on the optical blocking region OB may pass through the first insulating layer 156 and the second insulating layer 158, and may be reflected from or absorbed by the first conductive layer 152. The light reflected from the first conductive layer 152 may be partially absorbed by the first insulating layer 156. Further, when the optical blocking layer OBL includes an additional conductive layer, the light not absorbed by the first insulating layer 156 may be absorbed by the additional conductive layer. The first conductive layer 152 may absorb the energy of visible light and near-infrared light through the plasmon phenomenon on its surface. As the light reflected from the optical blocking region OB decreases, the quality degradation of the image signal that may occur in the image sensor 1000 due to the flare phenomenon may be prevented.

The optical blocking layer OBL may be disposed on the anti-reflection layer 110. A barrier metal layer for improving adhesion may be further disposed between the optical blocking layer OBL and the anti-reflection layer 110. The barrier metal layer may include, for example, titanium (Ti) and/or titanium nitride (TiN). The first conductive layer 152 may be formed with a relatively thick thickness, for example, 100 nm or more, in order to minimize the transmittance of incoming light, but embodiments are not limited thereto. The first conductive layer 152 may include a metal such as tungsten (W). The thickness of the first insulating layer 156 may be determined according to the wavelength of the absorbed light. For example, when the image sensor 1000 is a device that uses RGB visible light, the thickness of the first insulating layer 156 may be thinner compared to that of the first insulating layer 156 of the device that uses infrared light. The first insulating layer 156 may include, for example, silicon oxide. The second insulating layer 158 may operate as the anti-reflection layer 110. Accordingly, the second insulating layer 158 may be formed with a thickness in the Z direction corresponding to ¼ of the wavelength of light to be absorbed. The second insulating layer 158 may be formed in a multi-layer structure, and may include hafnium oxide (HfOₓ). The materials or thicknesses of the first conductive layer 152, the first insulating layer 156, and the second insulating layer 158 are not limited to the materials or values described above, and may be modified variously according to aspects.

A height from the anti-reflection layer 110 to the optical blocking layer OBL may be substantially equal to or lower than a height from the anti-reflection layer 110 to the color filters CF1 and CF2 in the pixel array region APS in the Z direction. By minimizing the height difference between the optical blocking layer OBL and the color filters CF1 and CF2 on the second surface 101b of the first substrate 101, defects in subsequent processes, such as formation of the micro lenses ML, may be improved.

The backside contact BCA may be disposed on the contact region BR1. The backside contact BCA may be formed through the anti-reflection layer 110 and disposed in a first trench T1 of the first substrate 101. The backside contact BCA may include the first conductive layer 152 and a first metal pattern 154a. A barrier metal layer may be further disposed below the first conductive layer 152. The first conductive layer 152 and the barrier metal layer may uniformly be disposed on and/or cover a side surface and a bottom surface of the first trench T1. The first metal pattern 154a may include, for example, aluminum (Al). However, the material of the first metal pattern 154a is not limited to aluminum. The first metal pattern 154a may fill the first trench T1. The backside contact BCA may be connected to the conductive pattern 106 of the PD isolation part DTI. The backside contact BCA may be applied with a predetermined voltage, for example, a ground voltage or a negative voltage, through the first conductive layer 152 and apply the voltage to the conductive pattern 106 of the PD isolation part DTI. As such, by applying the ground voltage or negative voltage to the conductive pattern 106 of the PD isolation part DTI through the backside contact BCA, holes that may be present on the surface of the side insulating layer 104 of the PD isolation part DTI are fixed, thus improving the dark current characteristics.

The backside via stack BVS may be disposed in the backside via stack region BR2. The backside via stack BVS may be disposed in a first hole HO1. The backside via stack BVS may extend in the Z direction in a structure that penetrates the anti-reflection layer 110, the first substrate 101, and the first interlayer insulating film IL1, and penetrates a portion of a second interlayer insulating film IL2. The backside via stacks BVS may electrically connect some of the first wiring lines 132 of the first semiconductor chip CH1 and some of second wiring lines 172 of the second semiconductor chip CH2 through the first conductive layer 152. The first holes HO1 may be filled with a protective pattern LRI. The protective pattern LRI may include an insulating material such as at least one of silicon oxide, aluminum oxide, tantalum oxide, or a combination thereof. Further, a capping pattern CFR may be disposed on the protection pattern LRI.

The pad PAD may be disposed in the pad region PR. The pad PAD may be disposed in a second trench T2. The pad PAD may include the first conductive layer 152 and a second metal pattern 154b. For example, the anti-reflection layer 110 may be disposed on a side surface and a bottom surface within the second trench T2. The first conductive layer 152 may uniformly be disposed on and/or cover the anti-reflection layer 110 within the second trench T2. The second metal pattern 154b may be disposed on the first conductive layer 152 and may fill the second trench T2. The second metal pattern 154b may include, for example, aluminum, but embodiments are not limited thereto.

As illustrated in FIG. 4, the backside vias BV may be arranged around and adjacent to the pad PAD. Likewise the backside via stacks BVS, the backside vias BV may be formed through the anti-reflection layer 110, the first substrate 101, and the first interlayer insulating film IL1 and through a portion of the second interlayer insulating film IL2. The backside vias BV may be connected to some of the second wiring lines 172 without being connected to the first wiring lines 132. The backside vias BV may be connected to the corresponding pads PAD through the first conductive layer 152. Signals input from outside the image sensor 1000 or output from the image sensor 1000 may be interfaced by the backside vias BV and the pads PAD.

Referring back to FIG. 5, the micro lenses ML may be disposed on the color filters CF1 and CF2 of the pixel array region APS. Edge portions of the micro lenses ML may be connected to each other. The micro lenses ML may be arranged in an array form. Accordingly, the micro lenses ML may form a micro lens array. Further, a single micro lens ML may be disposed on and/or cover one pixel. However, embodiments are not limited to the above, and in one or more embodiments, a single micro lens ML may cover a plurality of pixels. For example, when a plurality of pixels form one shared pixel, one micro lens ML may be disposed on and/or cover one shared pixel.

A lens residual layer MLR may be disposed on the optical blocking layer OBL of the peripheral region PE. The lens residual layer MLR may include the same material as a material of the micro lenses ML. A lens coating layer MLC may be disposed on and/or cover the micro lenses ML and the lens residual layer MLR. An opening OP may be formed in the pad region PR through the lens residual layer MLR and the lens coating layer MLC, exposing the pad PAD.

The second semiconductor chip CH2 may include a second substrate 160 and a second wiring layer 170. The second semiconductor chip CH2 may be disposed below the first semiconductor chip CH1, and the second wiring layer 170 of the second semiconductor chip CH2 may be coupled to the first wiring layer 130 of the first semiconductor chip CH1. A logic device transistor PTR may be disposed on the second substrate 160. The logic device transistor PTR may form circuit blocks (e.g., 200 to 700 in FIG. 1) of the image sensor 1000. In the second semiconductor chip CH2, an upper surface of the second substrate 160 may correspond to a front side which is an active surface. Further, the second wiring layer 170 may be disposed on the second substrate 160 and the logic device transistor PTR. The second wiring layer 170 may include the second interlayer insulating film IL2, the second wiring line 172, and a second via contact 174. The second interlayer insulating film IL2, the second wiring line 172, and the second via contact 174 may be formed in the same manner as the first interlayer insulating film IL1, the first wiring line 132, and the first via contact 134 of the first wiring layer 130.

In the image sensor 1000 according to various embodiments, the TiO₂ layer (see 114 in FIG. 7) included in the anti-reflection layer 110 may include a first region and a second region having different refractive indices. For example, such a difference in refractive indices may be caused by the combination of crystal phase of TiO₂ included in the first region and the second region. Further, the first region and the second region may be selectively disposed below the color filters CF1 and CF2. Through such a configuration, the image sensor 1000 according to various embodiments includes the anti-reflection layer 110 or the TiO₂ layer in which regions having different refractive indices are optimized and disposed, thereby minimizing the reflection of light in a specific region and increasing the amount of light incident on the photodiode PD.

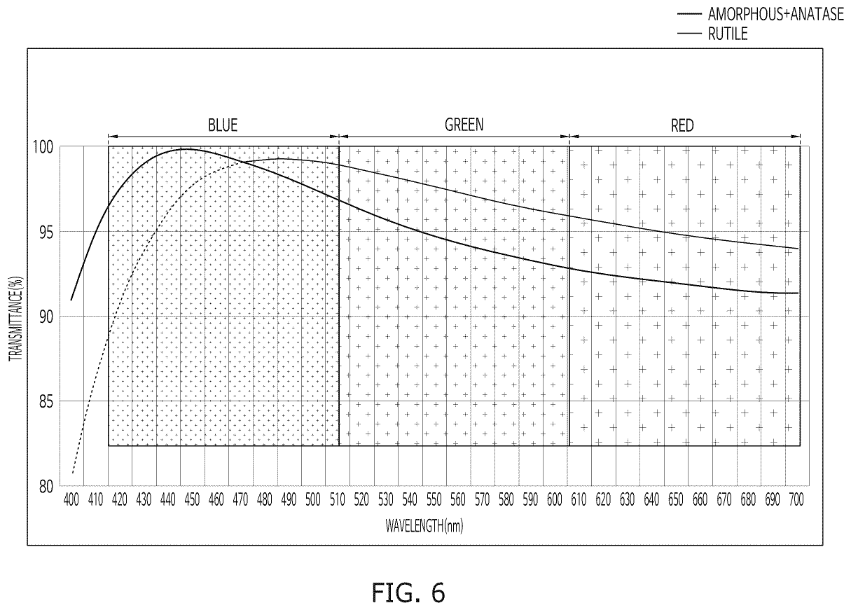

FIG. 6 is a graph illustrating the light transmittance according to the wavelength of each crystal phase of TiO₂.

Referring to FIG. 6, the transmittance of light for each wavelength band may vary depending on the combination of the crystal phases included in TiO₂. For example, in the case of TiO₂ including amorphous TiO₂ or anatase phase TiO₂, the transmittance of light may be higher in relatively lower wavelength bands. On the other hand, in the case of TiO₂ including rutile phase TiO₂, the transmittance of light may be higher in relatively higher wavelength bands. Specifically, in the case of TiO₂ including amorphous TiO₂ or anatase phase TiO₂, light in the blue range of the visible light spectrum can be effectively transmitted. Further, in the case of TiO₂ including rutile phase TiO₂, light in the green or red range of the visible light spectrum can be effectively transmitted.

Therefore, placing TiO₂ including amorphous TiO₂ or anatase phase TiO₂ below the blue filter where the light in the blue range of the visible light spectrum enters, and placing rutile phase TiO₂ below the green filter where the light in the green range of the visible light spectrum enters or below the red filter where the light in the red range of the visible light spectrum enters may improve light transmittance.

Additionally, placing rutile phase TiO₂ below at least the red filter where the light in the red range of the visible light spectrum enters may improve light transmittance. Further, placing TiO₂ including amorphous TiO₂ or anatase phase TiO₂ below the blue filter where the light in the blue range of the visible light spectrum enters may improve light transmittance.

In the image sensor 1000 according to various embodiments, by selectively configuring TiO₂ crystallinity included in the TiO₂ layer that forms the anti-reflection layer 110, the anti-reflection layer 110 with improved light transmittance can be provided. As a result, loss of the quantum efficiency (hereinafter, referred to as QE) due to the light absorption in the anti-reflection layer 110 can be prevented, thus improving the QE of the image sensor 1000.

In FIG. 6, although it is illustrated that the blue, green, and red ranges of the visible light spectrum are clearly divided according to the wavelengths of light, embodiments are not limited thereto, and two color ranges may appear together in the wavelengths that divide each of the blue, green, and red ranges of the visible light spectrum or in a specific wavelength range that includes these wavelengths.

FIG. 7 is a diagram provided to explain an image sensor according to one or more embodiments. FIG. 7 may correspond to a cross-sectional view of the II-II′ portion of FIG. 4. For convenience of description, only some of the components of the image sensor 1000 described in FIG. 4 or 5 are illustrated briefly in FIG. 7. In addition, unless specifically described to the contrary, the aspects described with reference to FIG. 7 will be understood with reference to the description of the same or similar components of the image sensor 1000 illustrated in FIG. 4 or FIG. 5.

Referring to FIG. 7, the image sensor 1000 may include the first substrate 101 including the first surface 101a and the second surface 101b opposite to each other in the Z direction, the first wiring layer 130 disposed on the first surface 101a of the first substrate 101, the anti-reflection layer 110 disposed on the second surface 101b of the first substrate 101, a color filter layer CFL disposed on the anti-reflection layer 110, and the micro lenses ML disposed on the color filter layer CFL. Further, the image sensor 1000 may include the second substrate 160 including a first surface 160a opposite to the first surface 101a of the first substrate 101 and the second wiring layer 170 disposed on the first surface 160a of the second substrate 160. The first wiring layer 130 may include the first wiring line 132 and the first interlayer insulating film IL1, and the second wiring layer 170 may include the second wiring line 172 and the second interlayer insulating film IL2. The first surface 101a of the first substrate 101 may be stacked opposite to the first surface 160a of the second substrate 160. For example, a lower surface of the first wiring layer 130 may be coupled to an upper surface of the second wiring layer 170.

The anti-reflection layer 110 may include an aluminum oxide (AlO) layer 112, a TiO₂ layer 114, and an hafnium oxide (HfOₓ) layer 116. The AlO layer 112 may be disposed between the second surface 101b of the first substrate 101 and the TiO₂ layer 114. Further, the HfOₓ layer 116 may be disposed between the color filter layer CFL and the TiO₂ layer 114. Additionally or alternatively, the HfOₓ layer 116 may be implemented as a plasma enhanced oxide (PEOX) layer, or the anti-reflection layer 110 may further include the PEOX layer. However, embodiments are not limited to the above, and the anti-reflection layer 110 may be formed in a stacked structure that may further include additional components or omit some components according to design conditions. In addition, the stacking order of each layer included in the anti-reflection layer 110 may be variously modified.

In one or more embodiments, the anti-reflection layer 110 may include the TiO₂ layer 114 including a first region having a first refractive index and a second region having a second refractive index higher than the first refractive index. For example, the first region may have a refractive index less than 2.5 at a wavelength of 633 nm. Further, the second region may have a refractive index of 2.5 or more at a wavelength of 633 nm. However, embodiments are not limited to the above, and a range of refractive indices represented by the first region and the second region may be variously modified. Further, the first region may partially have a refractive index of 2.5 or more, or the second region may partially have a refractive index of less than 2.5.

In one or more embodiments, as illustrated in FIG. 7, the TiO₂ layer 114 may be divided into a first region and a second region in a plan view. The first region may configure a part of the TiO₂ layer 114, and the second region may configure the rest of the TiO₂ layer 114. For example, at least a portion of the first region and at least a portion of the second region may be arranged to overlap in the X direction or Y direction that intersects with the Z direction. Further, the first region and the second region may be disposed to not overlap in the Z direction. However, embodiments are not limited to the above, and at least a portion of the first region and at least a portion of the second region may overlap in the Z direction in certain cases.

In one or more embodiments, the difference in the refractive indices between the first region and the second region may be caused by the combination of crystal phases of TiO₂ included in the first region and the second region. For example, the first region may include at least one of amorphous TiO₂ or anatase phase TiO₂, and the second region may include rutile phase TiO₂. For example, the first region may be a region that does not include rutile phase TiO₂, and the second region may be a region that includes rutile phase TiO₂. Since the second region includes rutile phase TiO₂ having a relatively high refractive index, the second region may have a higher refractive index than a refractive index of the first region that includes amorphous TiO₂ or anatase phase TiO₂.

TiO₂ included in the second region may not be entirely in the rutile phase. For example, the second region may further include at least one of partially amorphous TiO₂ or anatase phase TiO₂, and may primarily include rutile phase. For example, the first region may include a single crystalline phase of TiO₂ (e.g., anatase phase TiO₂), and the second region may include two or more different crystalline phases of TiO₂ (e.g., anatase phase TiO₂ and rutile phase TiO₂). Since the second region at least includes rutile phase TiO₂, and the first region does not at least include rutile phase TiO₂, a refractive index of the second region may be higher than a refractive index of the first region.

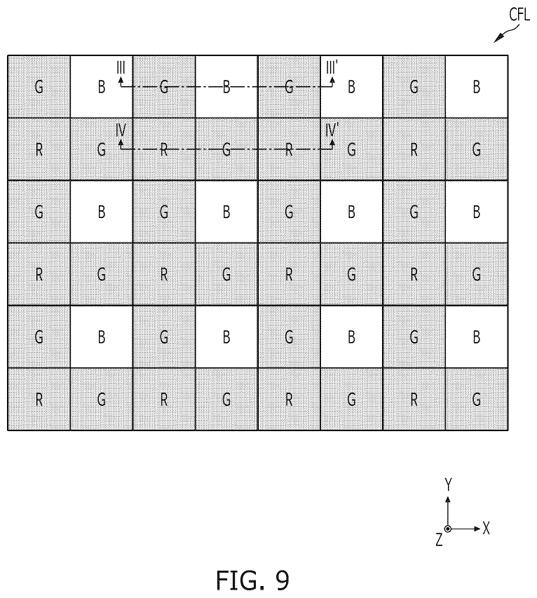

In one or more embodiments, the first region may be disposed below some of a plurality of color filters CF1, CF2, and CF3 included in the color filter layer CFL, and the second region may be disposed below the remaining color filters among the plurality of color filters CF1, CF2, and CF3 included in the color filter layer CFL. As illustrated in FIG. 7, the first region may be disposed below the color filters CF1 and CF3, and the second region may be disposed below the color filter CF2. The wavelength bands of light passed by each of the color filters CF1, CF2, and CF3 may be different. For example, the color filters CF1 and CF3 may be configured to transmit light of a first wavelength band, and the color filter CF2 may be configured to transmit light of a second wavelength band longer than the first wavelength band. Under such structure, the first region and the second region may be selectively arranged in the TiO₂ layer 114 to allow the light entering through the color filter layer CFL to proceed to the photodiodes PD1, PD2, and PD3 with relatively high transmittance. Embodiments of placing the first region and the second region will be described below with reference to FIGS. 9 to 14.

FIG. 8 is a diagram provided to explain the color filter layer according to one or more embodiments. The color filter layer CFL may be disposed in the pixel array region APS of FIG. 1.

Referring to FIG. 8, the color filter layer CFL may be arranged in a Bayer pattern that is commonly selected in a general image sensor. One unit pattern may include four quadrant regions, and a blue filter B, a first green filter G, a red filter R, and a second green filter G may be disposed in the first to fourth quadrants, respectively. These unit patterns may be repeatedly arranged along the X and Y directions.

The first green filter G and the second green filter G may be disposed in one diagonal direction within the unit pattern in the form of 2×2 array, and the blue filter B and the red filter R may be disposed in the other diagonal direction, respectively. For example, a first row in which a plurality of first green filters G and a plurality of blue filters B are alternately disposed in the X direction, and a second row in which a plurality of red filters R and a plurality of second green filters G are alternately disposed in the X direction may be repeatedly disposed in the Y direction.

In one or more embodiments, the color filter layer CFL may be arranged in the form of a tetra pattern, in which one color filter among the red filter R, the green filter G, or the blue filter B is disposed for each of 4 unit pixels arranged in 2×2 array to form a 4×Bayer pattern, or a tetra pattern, in which one color filter among the red filter R, the green filter G, or the blue filter B is disposed for each of 16 unit pixels arranged in 4×4 array to form a 8×8 Bayer pattern. Hereinbelow, an example of the color filter layer CFL arranged in the form of a Bayer pattern will be described, but aspects are not limited thereto and can be applied to patterns other than the Bayer pattern.

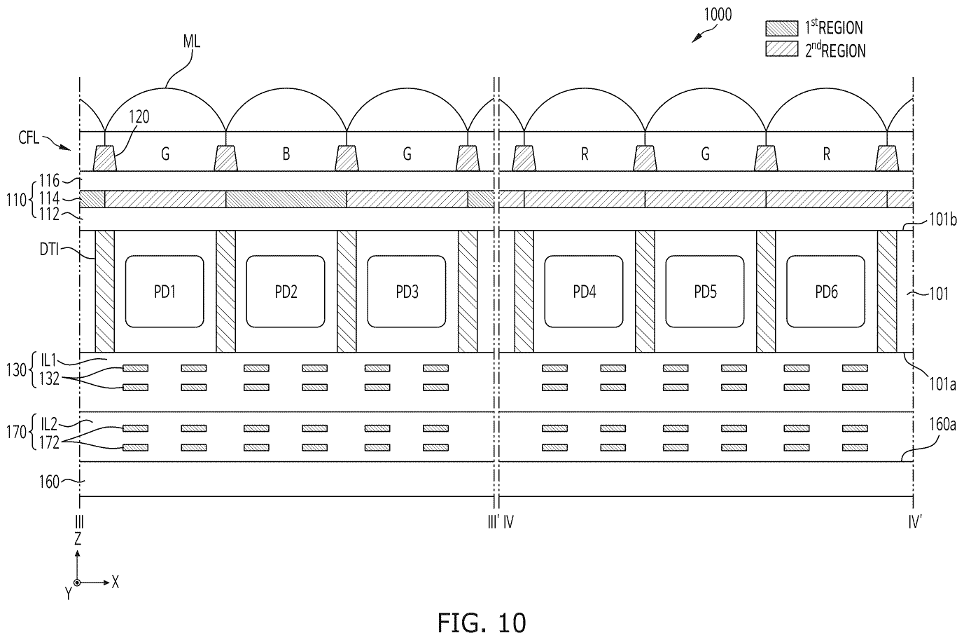

FIG. 9 is a diagram provided to explain an arrangement of the first region and the second region below the color filter layer according to one or more embodiments. FIG. 10 is a diagram provided to explain the image sensor according to one or more embodiments. FIG. 10 may correspond to a cross-sectional view of the III-III′ and IV-IV′ portions of FIG. 9. The aspects described below can be understood to be similar to the image sensor 1000 described in FIG. 7, except for the arrangement of the first region and the second region. Therefore, unless specifically described to the contrary, the aspects described with reference to FIGS. 9 and 10 will be understood with reference to the description of the same or similar components of the image sensor 1000 illustrated in FIG. 7.

Referring to FIGS. 9 and 10, in one or more embodiments, the first region of the TiO₂ layer 114 may be disposed below the blue filter B among a plurality of color filters included in the color filter layer CFL, and the second region of the TiO₂ layer 114 may be disposed below the red filter R and the green filter G among the plurality of color filters included in the color filter layer CFL. In FIG. 9, it may be understood that the second regions are disposed below the shaded regions.

Referring to the description of FIG. 6, TiO₂ including amorphous TiO₂ or anatase phase TiO₂ may more effectively transmit light in the wavelength band that the blue filter B allows to pass through. In addition, TiO₂ including rutile phase TiO₂ may more effectively transmit the light in the wavelength band that the green filter G or the red filter R allows to pass through.

Thus, in the image sensor 1000 according to one or more embodiments, the second region including rutile phase TiO₂ may be disposed below the green filter G or the red filter R, and the first region including amorphous TiO₂ or anatase phase TiO₂ may be disposed below the blue filter B. Through such a configuration, the QE loss due to light absorption in the TiO₂ layer 114 included in the anti-reflection layer 110 may be reduced. Accordingly, sensitivity of the image sensor 1000 may be more effectively improved.

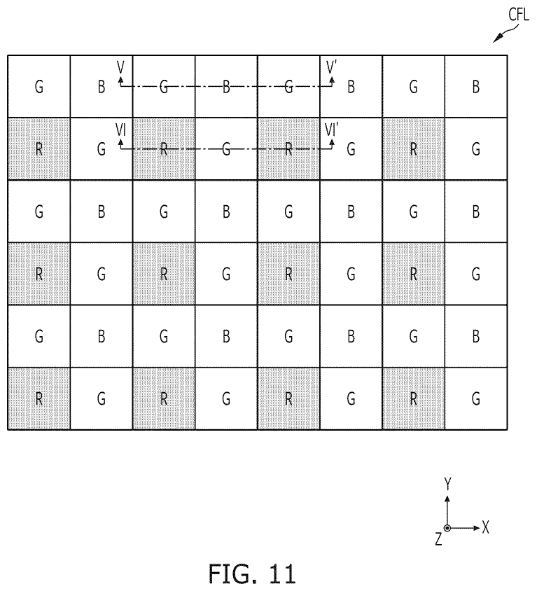

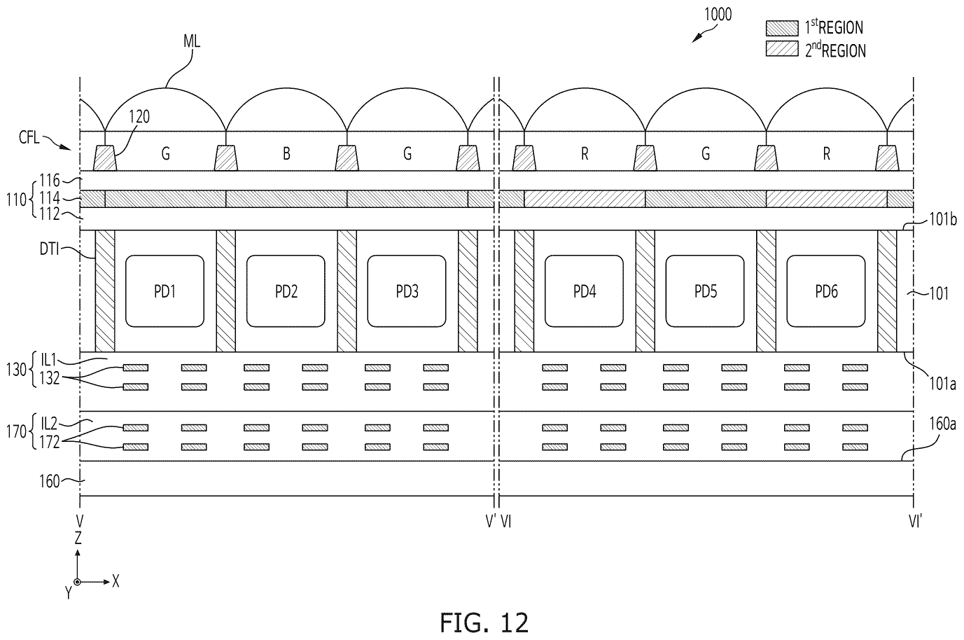

FIG. 11 is a diagram provided to explain an arrangement of the first region and the second region below the color filter layer according to one or more embodiments. FIG. 12 is an example diagram provided to explain the image sensor according to one or more embodiments. FIG. 12 may correspond to a cross-sectional view of the V-V′ and VI-VI′ portions of FIG. 11. The aspects described below can be understood to be similar to the image sensor 1000 described in FIG. 7, except for the arrangement of the first region and the second region. Therefore, unless specifically described to the contrary, the aspects described with reference to FIGS. 11 and 12 will be understood with reference to the description of the same or similar components of the image sensor 1000 illustrated in FIG. 7.

Referring to FIGS. 11 and 12, in one or more embodiments, the first region of the TiO₂ layer 114 may be disposed below the blue filter B or the green filter G among the plurality of color filters included in the color filter layer CFL, and the second region of the TiO₂ layer 114 may be disposed below the red filter R among the plurality of color filters included in the color filter layer CFL. In FIG. 11, it may be understood that the second regions are disposed below the shaded regions.

Referring to FIG. 6, placing rutile phase TiO₂ at least below the red filter R, and placing TiO₂ including amorphous TiO₂ or anatase phase TiO₂ at least below the blue filter B may improve light transmittance.

Therefore, in the image sensor 1000 according to one or more embodiments, the second region including rutile phase TiO₂ may be disposed below the red filter R, and the first region including amorphous TiO₂ or the anatase phase TiO₂ may be disposed below the blue filter B and the green filter G. Through such a configuration, the QE loss due to light absorption in the TiO₂ layer 114 included in the anti-reflection layer 110 can be reduced. Accordingly, sensitivity of the image sensor 1000 may be more effectively improved.

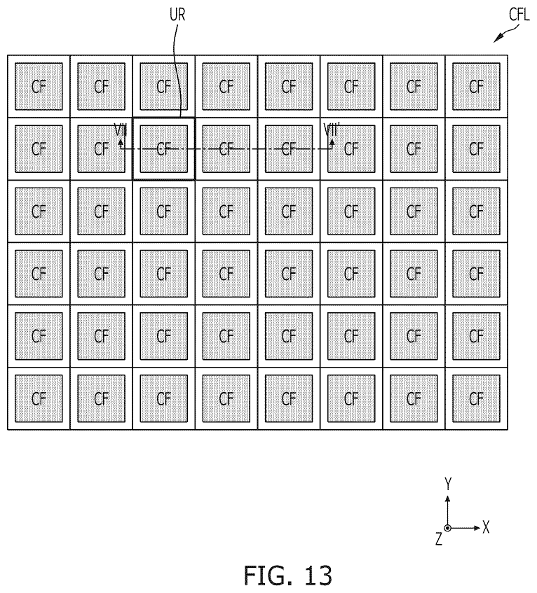

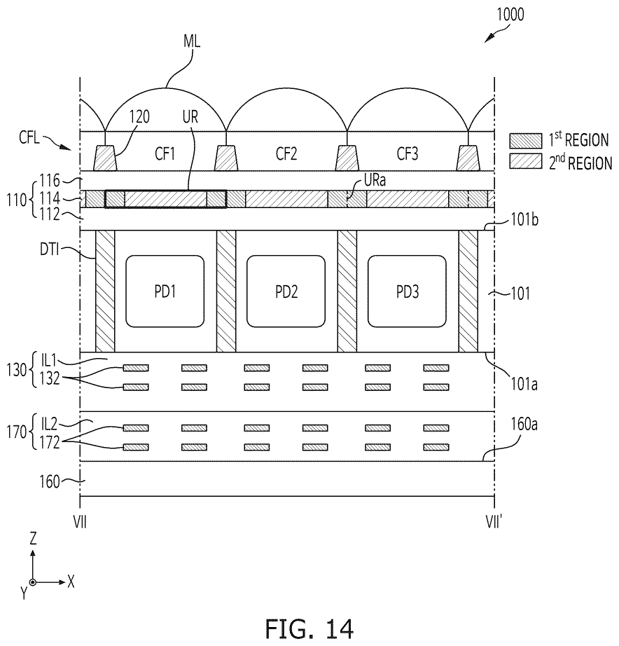

FIG. 13 is a diagram provided to explain an arrangement of the first region and the second region below the color filter layer according to one or more embodiments. FIG. 14 is an example diagram provided to explain the image sensor according to one or more embodiments. FIG. 14 may correspond to a cross-sectional view of the VII-VII-′ portion of FIG. 13. The aspects described below can be understood to be similar to the image sensor 1000 described in FIG. 7, except for the arrangement of the first region and the second region. Therefore, unless specifically described to the contrary, the aspects described with reference to FIGS. 13 and 14 will be understood with reference to the description of the same or similar components of the image sensor 1000 illustrated in FIG. 7.

Referring to FIG. 13, in one or more embodiments, the TiO₂ layer 114 may include a plurality of unit regions UR corresponding to a plurality of color filters CF included in the color filter layer CFL. In FIG. 13, it may be understood that the second region is disposed below the shaded regions. Referring to FIGS. 13 and 14, the unit regions UR of the TiO₂ layer 114 may correspond one-to-one with the color filters CF, and one unit region UR may be disposed below each color filter CF. Although FIG. 14 illustrates that only one unit region UR is included in the TiO₂ layer 114, one unit region UR may be disposed below each of the plurality of color filters CF1, CF2, and CF3.

In one or more embodiments, each of the plurality of unit regions UR may include a first region and a second region. For example, one unit region UR may include both the first region having a first refractive index and the second region having a second refractive index higher than the first refractive index. For example, as illustrated in FIGS. 13 and 14, from a planar perspective, the second region may be disposed at the center of the unit region UR, and the first region may be disposed in the periphery of the unit region UR to surround the second region.

In one or more embodiments, a plurality of unit regions UR may include a first unit region and a second unit region adjacent to the first unit region. For example, in FIG. 14, among a plurality of unit regions UR included in the TiO₂ layer 114, a region below the color filter CF1 is the first unit region, and a region below the color filter CF2 is the second unit region. In this case, the second region may be disposed in each of the first unit region and the second unit region, and the first region may be disposed in an area (e.g., a region) that includes a boundary between the first unit region and the second unit region. Further, the first region may be formed to be adjacent to and surround at least a portion of the second region. In FIG. 13, the second region occupies most of the unit region UR, and the first region occupies only a partial area at a boundary of the unit region UR, but embodiments are not limited thereto. The area occupied by each of the first region and the second region or the shape of the occupied area may be variously modified according to embodiments.

According to various embodiments, the second region having a relatively higher refractive index than a refractive index of the first region may be disposed at the center of the unit region UR of the TiO₂ layer 114. Through such a configuration, the light incident on the center of the unit region UR may be concentrated vertically downward due to the relatively high refractive index of the second region. For example, when the light incident at a specific angle reaches the second region, the light may be refracted and concentrated in the center due to the high refractive index of the second region. Accordingly, the amount of light transmitted to the photodiode PD may be increased, and optical crosstalk to the adjacent pixels may be reduced.

According to various embodiments, the first region having a relatively lower refractive index than the second region may be disposed at a boundary of the unit regions UR of the TiO₂ layer 114 to be adjacent to and surround the second region. The light incident on the boundary of the unit region UR may undergo diffraction as it passes through the first region, which has a lower refractive index, and be scattered at various angles. For example, when the light passes through the boundary, some of the light spreads to the surrounding area, but a portion of it may be guided to the second region disposed in the center. Furthermore, since the second region has a relatively high refractive index, when the diffracted light reaches the second region, the optical path may be refracted, resulting in a light-concentrating effect that focuses the light in the vertical direction. Through such a configuration, the loss of light passing through the TiO₂ layer 114 may be reduced, and the QE loss due to light absorption can be effectively reduced.

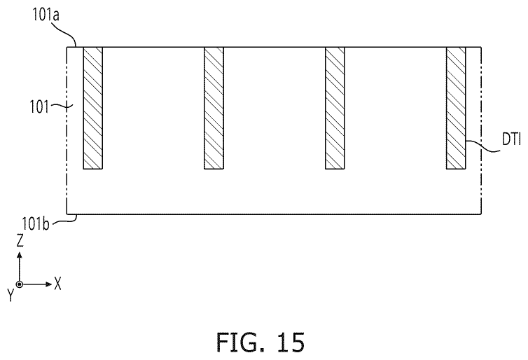

FIGS. 15 to 28 are cross-sectional views sequentially illustrating a method of manufacturing the image sensor. The components or operations already described above in FIGS. 1 to 14 may be briefly described or may not be described.

Referring to FIG. 15, the PD isolation part DTI may be formed on the first substrate 101 that includes the first surface 101a and the second surface 101b opposite to each other. The first substrate 101 may include a silicon substrate. The first surface 101a may be a front side of the substrate to which semiconductor process is applied, and the second surface 101b may be a back side before grinding.

A trench may be formed on the first surface 101a of the first substrate 101, extending from the first surface 101a toward the second surface 101b, using a mask pattern, and an insulating material may be filled into the trench to form the PD isolation part DTI. The PD isolation part DTI may be formed to not penetrate the first substrate 101, but the PD isolation part DTI may be formed as illustrated in FIG. 7 in the subsequent stage by exposing the PD isolation part DTI to the second surface 101b through grinding of the second surface 101b. However, embodiments are not limited thereto, and the trench may be formed to penetrate through the first substrate 101, so that a through-structure PD isolation part DTI may be formed in this stage. Further, according to embodiments, the PD isolation part DTI may be formed in a FDTI structure extending from the first surface 101a to the second surface 101b of the first substrate 101, but depending on embodiments, the PD isolation part DTI may be formed in a BDTI structure extending from the second surface 101b to the first surface 101a of the first substrate 101.

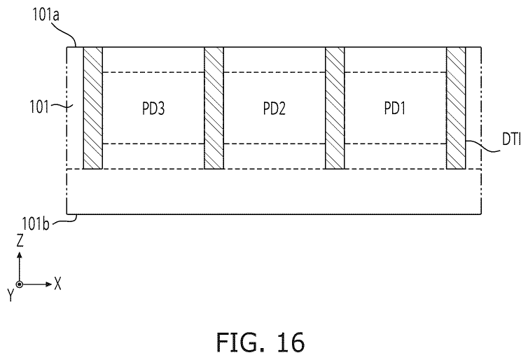

Referring to FIG. 16, photodiodes PD1, PD2, and PD3 may be formed on the first substrate 101 separated by the PD isolation part DTI.

Through an ion implantation process, the photodiodes PD1, PD2, and PD3 doped with impurities of the second conductivity type opposite to the impurities of the first conductivity type may be formed in the first substrate 101 doped with impurities of the first conductivity type. For example, the impurities of the first conductivity type may be P-type, and the impurities of the second conductivity type may be N-type. The phototransistor, photo gate, pinned photodiode, or a combination thereof may be implemented instead of the photodiode as a photoelectric conversion device.

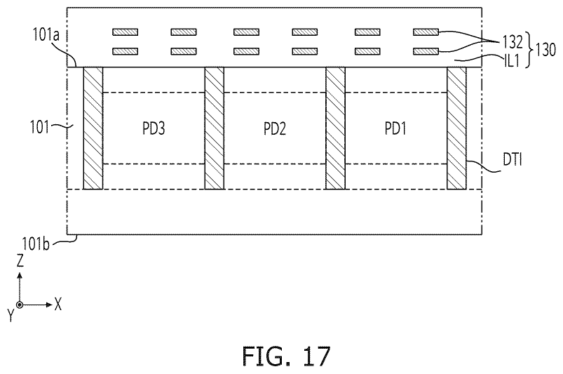

Referring to FIG. 17, the first wiring layer 130 may be formed on the first surface 101a of the first substrate 101.

The first wiring layer 130 may include the first interlayer insulating film IL1 and the first wiring line 132. The first wiring layer 130 may further include a first via contact (e.g., 134 of FIG. 5). The first via contact may be formed on the first surface 101a of the first substrate 101.

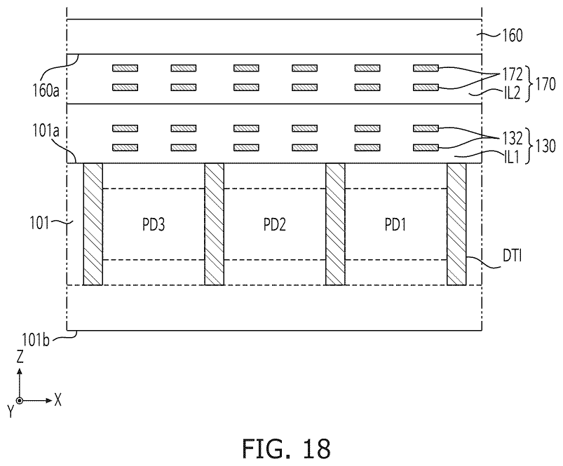

Referring to FIG. 18, the second substrate 160 and the second wiring layer 170 may be coupled to the first substrate 101 and the first wiring layer 130.

The first surface 101a of the first substrate 101 may be coupled to be opposite to the first surface 160a of the second substrate 160. For example, the lower surface of the first wiring layer 130 may be coupled to the upper surface of the second wiring layer 170. The first wiring layer 130 and the second wiring layer 170 may be bonded by, for example, a wafer bonding process, but embodiments are not limited thereto.

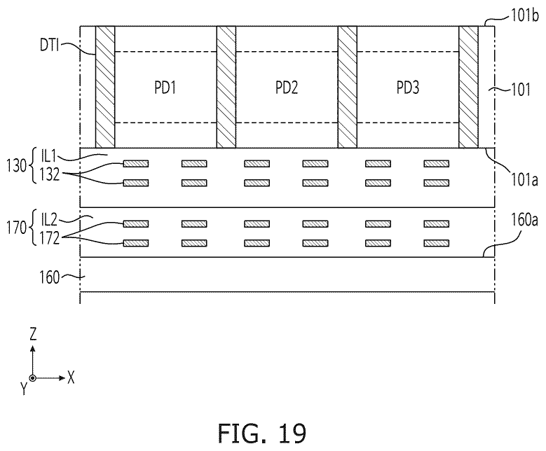

Referring to FIG. 19, the second surface 101b of the first substrate 101 may be ground so that the first substrate 101 has a predetermined thickness. The first substrate 101 may be polished up to the part GP in FIG. 18, so that the PD isolation part DTI may be exposed through the second surface 101b of the first substrate 101.

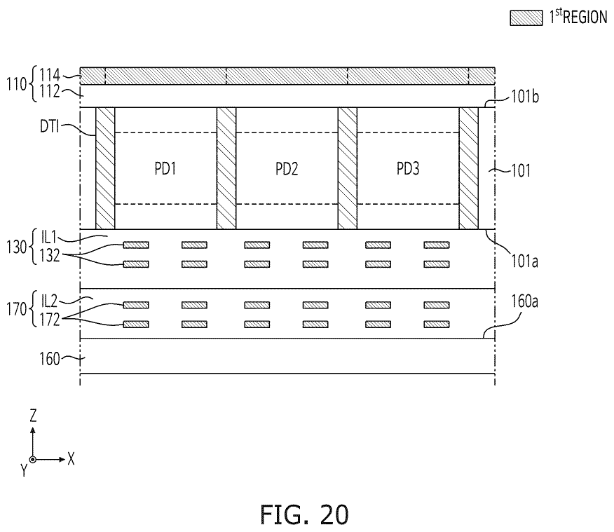

Referring to FIG. 20, the anti-reflection layer 110 may be formed on the second surface 101b of the first substrate 101.

The anti-reflection layer 110 may include the AlO layer 112 and the TiO₂ layer 114. According to one or more embodiments, the AlO layer 112 may be referred to as a passivation layer. However, embodiments are not limited to the above, and the anti-reflection layer 110 may be formed to further include additional components or omit some components. For example, the anti-reflection layer 110 may further include at least one of an HfOₓlayer or a PEOX layer.

The TiO₂ layer 114 may include at least one of amorphous TiO₂, anatase phase TiO₂, and a combination thereof. For example, the TiO₂ layer in this manufacturing stage may not include the rutile phase TiO₂. Therefore, the TiO₂ layer in this manufacturing stage may include the first region and may not include the second region. Hereinbelow, a method of forming the second region including rutile phase TiO₂ in a specific region of the TiO₂ layer will be described.

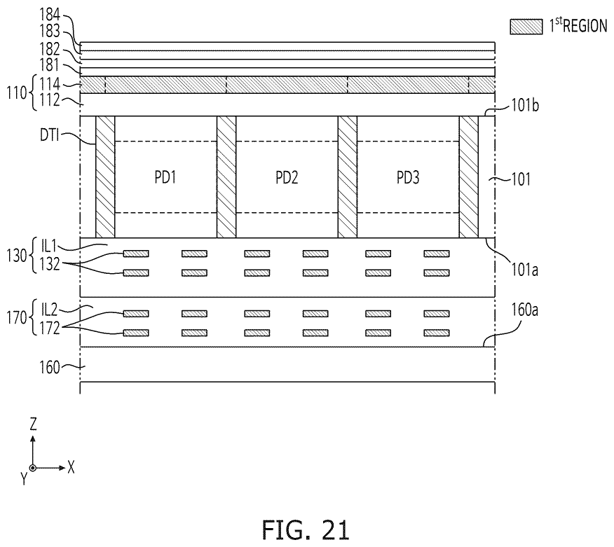

Referring to FIG. 21, a lower protective layer 181, a hard mask 182, an upper protective layer 183, and a photoresist 184 may be formed in order on the anti-reflection layer 110.

The lower protective layer 181 may be formed on the anti-reflection layer 110. The lower protective layer 181 may protect the TiO₂ layer 114 in a laser annealing process which will be performed later, and may play a role of reducing damage to the TiO₂ layer 114. The lower protective layer 181 may include a transparent material to allow sufficient light transmission to the TiO₂ layer 114, and may include an oxide-based material. Additionally, the lower protective layer 181 may include a material having relatively high thermal conductivity, and therefore, contribute to maintaining uniform distribution of heat during laser annealing. In one or more embodiments, the lower protective layer 181 may include silicon oxide, aluminum oxide, etc. However, embodiments are not limited to the above, and a suitable material may be selected according to processing conditions. In one or more embodiments, the operation of forming the lower protective layer 181 may be omitted.

The hard mask 182 may be formed on the lower protective layer 181. In one or more embodiments, when the lower protective layer 181 is omitted, the hard mask 182 may be formed on the anti-reflection layer 110. The hard mask 182 may operate as a mask in the subsequent patterning and etching processes and selectively protect or block a region other than a specific region of the TiO₂ layer 114 so that the specific region is exposed to the laser annealing process. In one or more embodiments, the hard mask 182 may include a metal material to prevent damage to the TiO₂ layer 114 during the subsequent processes. For example, the hard mask 182 may include a material such as titanium nitride (TiN), titanium (Ti), tungsten (W), and aluminum (Al), but aspects are not limited thereto.

The upper protective layer 183 may be formed on the hard mask 182. Forming the upper protective layer 183 may improve the accuracy of pattern formation of the photoresist 184 and improve the etching selectivity. In one or more embodiments, the upper protective layer 183 may include an oxide-based material (SiO₂) or a nitride-based material (SiN). However, aspects are not limited to the above, and a suitable material may be selected according to processing conditions. In addition, depending on the requirements of specific processes, a silicon oxynitride (SiON) layer or a silicon oxide (SOH) layer may be additionally formed adjacent to the upper protective layer 183. In one or more embodiments, the operation of forming the upper protective layer 183 may be omitted.

The photoresist 184 may be formed on the upper protective layer 183. In one or more embodiments, when the upper protective layer 183 is omitted, the photoresist 184 may be formed on the hard mask 182.

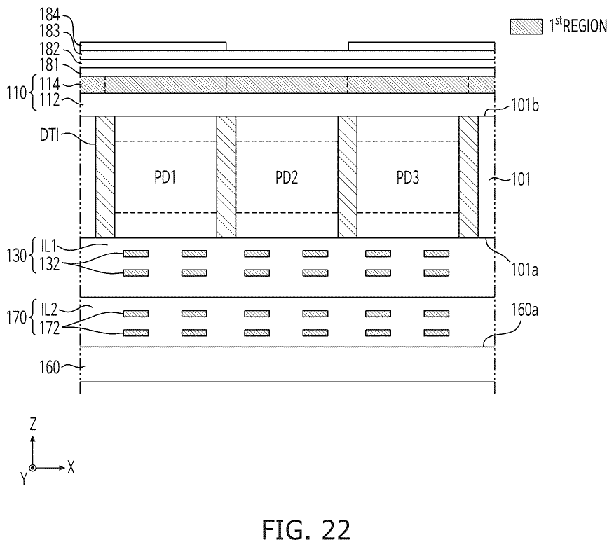

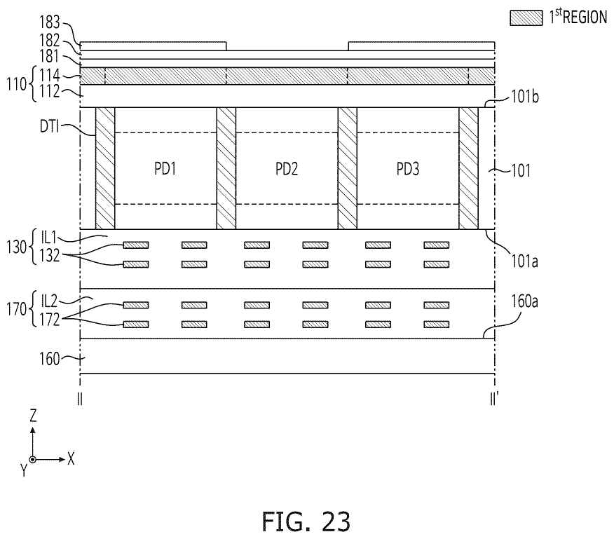

Referring to FIG. 22, the photoresist 184 may be patterned on the upper protective layer 183. The photoresist 184 may be removed except for a region of the upper protective layer 183 that is not intended to be removed. Referring to FIG. 23, the upper protective layer 183 may be removed using the pattern of the photoresist 184 as a mask. Further, after the upper protective layer 183 is removed, the remaining photoresist 184 may be removed.

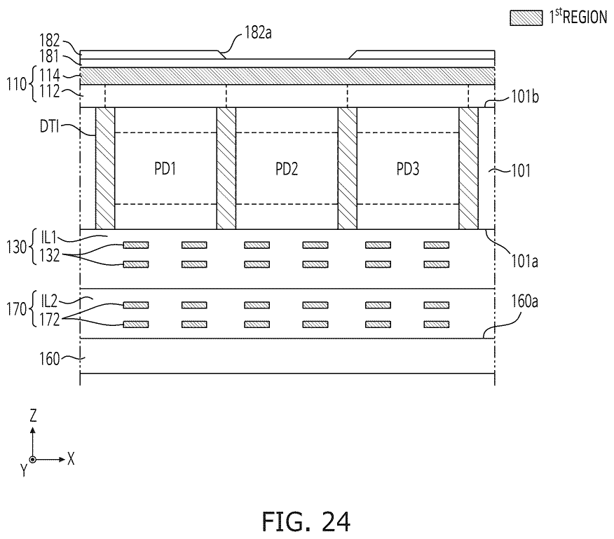

Referring to FIG. 24, the patterned hard mask 182 may be formed. In one or more embodiments, the hard mask 182 may be patterned to include a tapered shape 182a that has a constant angle with respect to the Z direction. Additionally or alternatively, the hard mask 182 may be patterned to include a side surface that is parallel to the Z direction. In one or more embodiments, only a specific region of the hard mask 182 may be etched using the upper protective layer 183 as an etch mask. Additionally or alternatively, if the upper protective layer 183 is not formed, only a specific region of the hard mask 182 may be etched, using the patterned photoresist 184 as an etch mask.

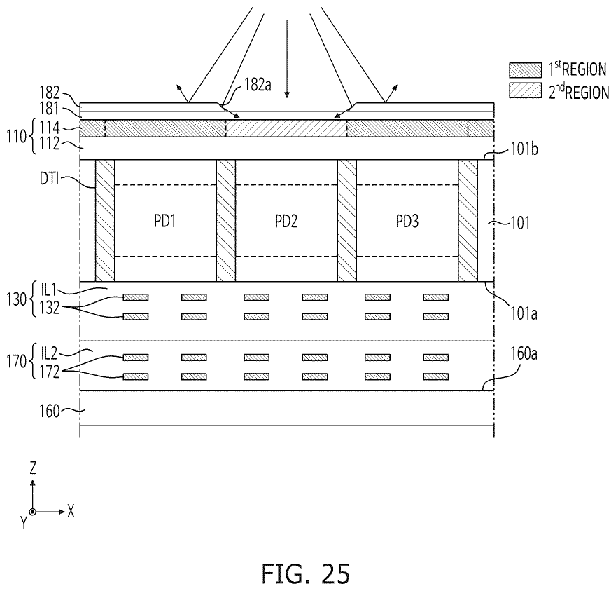

Referring to FIG. 25, the second region may be formed by performing the laser annealing process on a specific region of the TiO₂ layer 114 exposed by the hard mask 182. As illustrated in FIG. 25, the laser may selectively irradiate the specific region of the TiO₂ layer 114 through the configuration of the patterned hard mask 182, which includes the tapered shape 182a. Through this manufacturing process, the rutile phase TiO₂ may be formed in the region where laser annealing has been performed. As described above, the region where the rutile phase TiO₂ is formed may be referred to as the second region. By including the rutile phase TiO₂, the second region may have a relatively high refractive index (about 2.5 to 2.7). As a result, the optical characteristics of a specific wavelength may be improved, and the sensitivity of the image sensor may be more effectively improved.

In one or more embodiments, technique of rapidly heating only the specific region of the TiO₂ layer 114 using a short-wavelength laser in nano-second range for a very short time may be applied in the laser annealing process. Using the short-wavelength laser with high energy concentration, the specific region of the TiO₂ layer 114 may instantaneously reach a temperature (about 950 to 1600° C.) sufficient to induce phase change. In addition, by irradiating (emitting) a short-wavelength laser for a very short time, the annealing depth may be limited to or less than 1 μm. Accordingly, heat transfer can be minimized except for the region where the phase change of the TiO₂ layer 114 occurs, so that the thermal effect on the first substrate 101 or other adjacent layers may be minimized.

However, embodiments are not limited to the laser annealing described above, and various other laser-based annealing technologies may be applied. The laser-based annealing technology may be characterized by a short-wavelength laser and a very short irradiation time in nano-second (ns) range. For example, to induce phase changes of TiO₂ by delivering high energy locally for a short time, the pulsed laser annealing (PLA) technology, the short pulse processing (SPP) technology, the laser thermal annealing (LTA) technology, etc. may be applied.

In addition to the laser-based annealing, various other annealing technologies may be applied. For example, various annealing techniques such as rapid thermal annealing (RTA), flash lamp annealing (FLA), microwave annealing, or furnace annealing may be applied. Each of these technologies may be selectively used to convert anatase phase TiO₂ into rutile phase TiO₂, and optimal phase change may be implemented through control of temperature, time, and energy depending on the process conditions.

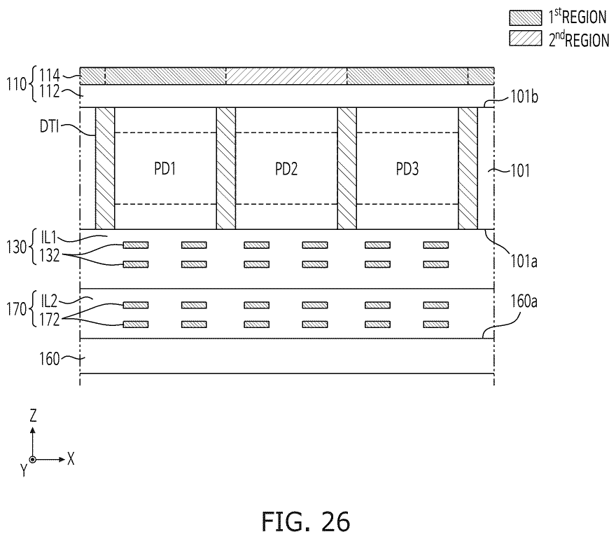

Referring to FIG. 26, the lower protective layer 181 and the hard mask 182 above the anti-reflection layer 110 may be removed. The lower protective layer 181 and the hard mask 182 may be removed by an etching process. For example, the etching process may include a dry etching process or a wet etching process, but embodiments are not limited thereto.

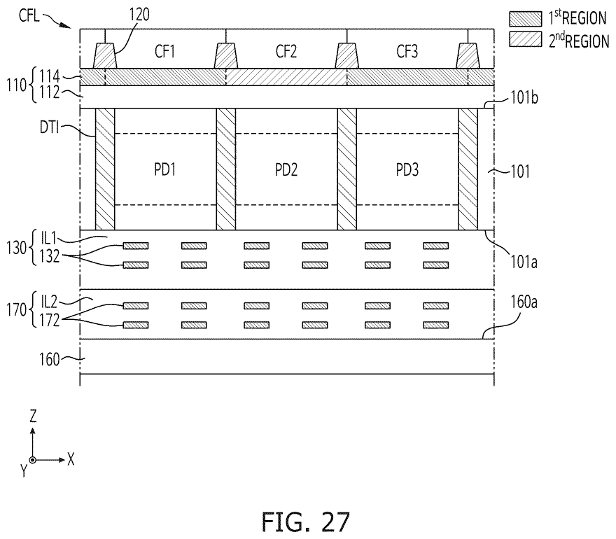

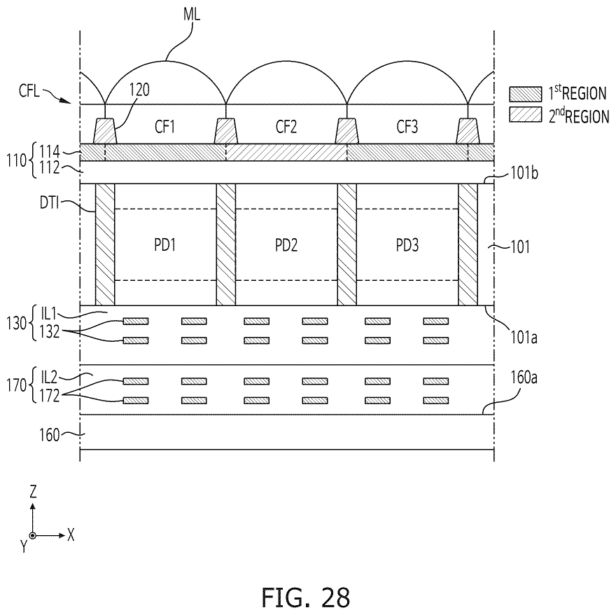

Referring to FIG. 27, the color filter layer CFL may be formed on the anti-reflection layer 110, and the lattice pattern 120 for separating the color filters CF1, CF2, and CF3 may be formed. In one or more embodiments, a portion (e.g., a partial region) of the color filter layer CFL may be disposed on the first region of the TiO₂ layer 114, and the remaining portion (e.g., the remaining region) of the color filter layer CFL may be disposed on the second region of the TiO₂ layer 114. Referring to FIG. 28, the micro lenses ML may be formed on the color filter layer CFL.

According to various embodiments, by including the anti-reflection layer in which regions having different refractive indices are disposed in the image sensor, reflection of light in a specific region may be minimized and the amount of light incident on the photodiode may be increased.

According to various embodiments, pixel sensitivity of an image sensor may be improved, and performance or image quality of the image sensor may be more effectively improved.

According to various embodiments, by selectively applying the rutile phase TiO₂ having a relatively high refractive index, the optical characteristics at specific wavelengths may be improved, and sensitivity of the image sensor may be more effectively improved.

According to various embodiments, in the process of forming the rutile phase TiO₂, thermal effects on the lower substrates or other adjacent layers may be minimized.

While embodiments have been described with reference to the figures, it will be understood by those of ordinary skill in the art that various changes in form and details may be made therein without departing from the spirit and scope as defined by the following claims and their equivalents.

What is claimed is

1. An image sensor, comprising:
a substrate comprising a first surface and a second surface opposite to each other in a first direction;
a wiring layer on the first surface of the substrate;
an anti-reflection layer on the second surface of the substrate, the anti-reflection layer comprising a TiO₂ layer that comprises a first region having a first refractive index and a second region having a second refractive index greater than the first refractive index; and
a plurality of color filters on the anti-reflection layer,
wherein at least a portion of the second region and at least a portion of the first region overlap with each other in a second direction that intersects with the first direction.

2. The image sensor according to claim 1, wherein the second region comprises rutile phase TiO₂.

3. The image sensor according to claim 2, wherein the first region comprises at least one of amorphous TiO₂ or anatase phase TiO₂, and
wherein the second region further comprises at least one of the amorphous TiO₂ or the anatase phase TiO₂.

4. The image sensor according to claim 1, wherein the first region is on some color filters of the plurality of color filters, and
wherein the second region is on remaining color filters of the plurality of color filters.

5. The image sensor according to claim 4, wherein each color filter of the plurality of color filters comprises one of a red filter, a blue filter, or a green filter,
wherein the first region is on the blue filter, and
wherein the second region is on the red filter or the green filter.

6. The image sensor according to claim 4, wherein each color filter of the plurality of color filters comprises one of a red filter, a blue filter, or a green filter,
wherein the first region is on the blue filter or the green filter, and
wherein the second region is on the red filter.

7. The image sensor according to claim 1, wherein the plurality of color filters comprise a first color filter configured to transmit a light in a first wavelength band and a second color filter configured to transmit a light in a second wavelength band greater than the first wavelength band,
wherein the first region is on the first color filter, and
wherein the second region is on the second color filter.

8. The image sensor according to claim 1, wherein the first region comprises a single crystalline phase of TiO₂, and
wherein the second region comprises two or more different crystalline phases of TiO₂.

9. The image sensor according to claim 1, wherein the substrate comprises a photoelectric conversion element (PD) region that comprises a plurality of photoelectric conversion elements that are disposed in a two-dimensional array and a peripheral region outside the PD region, and
wherein the second region is on the PD region.

10. The image sensor according to claim 1, wherein the TiO₂ layer comprises a plurality of unit regions corresponding to the plurality of color filters, and
wherein each unit region of the plurality of unit regions comprises the first region and the second region.

11. The image sensor according to claim 10, wherein the plurality of unit regions comprise a first unit region and a second unit region adjacent to the first unit region,
wherein the second region is in each of the first unit region and the second unit region, and
wherein the first region is in an area comprising a boundary between the first unit region and the second unit region and adjacent to at least a portion of the second region.

12. The image sensor according to claim 1, wherein the anti-reflection layer further comprises at least one of an AlO layer, an HfOₓ layer, or a plasma enhanced oxide (PEOX) layer.

13. An image sensor, comprising:
a first semiconductor chip comprising:
a first substrate comprising a photoelectric conversion element (PD) region that comprises a plurality of photoelectric conversion elements in a two-dimensional array and a peripheral region outside the PD region; and
a first wiring layer on a first surface of the first substrate;
a second semiconductor chip on the first semiconductor chip, the second semiconductor chip comprising a second substrate, a logic device being on the second substrate and a second wiring layer being on a first surface of the second substrate;
an anti-reflection layer on a second surface of the first substrate opposite to the first surface of the first substrate, the anti-reflection layer comprising a first region having a first refractive index and a second region having a second refractive index greater than the first refractive index; and
a color filter layer on the anti-reflection layer and comprising a plurality of color filters in a two-dimensional array within the PD region,
wherein the first region is on a first portion of the color filter layer, and
wherein the second region is on a second portion of the color filter layer other than the first portion of the color filter layer.

14. The image sensor according to claim 13, wherein the first region and the second region comprise a same material.

15. The image sensor according to claim 13, wherein the second region comprises a rutile phase TiO₂.

16. The image sensor according to claim 13, wherein the first region comprises at least one of amorphous TiO₂ or anatase phase TiO₂, and
wherein the second region further comprises at least one of the amorphous TiO₂ or the anatase phase TiO₂.

17. The image sensor according to claim 13, wherein the plurality of color filters comprise a first color filter configured to transmit a light in a first wavelength band and a second color filter configured to transmit a light in a second wavelength band greater than the first wavelength band,
wherein the first portion of the color filter layer comprises a region in which the first color filter is disposed, and
wherein the second portion of the color filter layer comprises a region in which the second color filter is disposed.

18. The image sensor according to claim 13, wherein each color filter of the plurality of color filters comprises one of a red filter, a blue filter, or a green filter,
wherein the first region is on the blue filter, and
wherein the second region is on the red filter or the green filter.

19. The image sensor according to claim 13, wherein each color filter of the plurality of color filters comprises one of a red filter, a blue filter, or a green filter,
wherein the first region is on the blue filter or the green filter, and
wherein the second region is on the red filter.

20. An image sensor, comprising:
a first semiconductor chip comprising:
a first substrate that comprises a first surface and a second surface opposite to each other in a first direction; and
a first wiring layer on the first surface of the first substrate, the first substrate comprising a photoelectric conversion element (PD) region that comprises a plurality of photoelectric conversion elements in a two-dimensional array and a peripheral region outside the PD region;
a second semiconductor chip on the first semiconductor chip, the second semiconductor chip comprising a second substrate, a logic device being on the second substrate and a second wiring layer being on a first surface of the second substrate;
an anti-reflection layer on the second surface of the first substrate, the anti-reflection layer comprising a TiO₂ layer that comprises a first region having a first refractive index and a second region having a second refractive index greater than the first refractive index; and
a color filter layer on the anti-reflection layer, the color filter layer comprising a plurality of color filters in a two-dimensional array within the PD region,
wherein at least a portion of the second region and at least a portion of the first region overlap with each other in a second direction that intersects with the first direction,
wherein the first region comprises at least one of amorphous TiO₂ or anatase phase TiO₂,
wherein the second region comprises rutile phase TiO₂ and at least one of the amorphous TiO₂, or the anatase phase TiO₂,
wherein each color filter of the plurality of color filters comprises one of a red filter, a blue filter, or a green filter,
wherein the first region is on the blue filter, and
wherein the second region is on the red filter or the green filter.
